(19) United States
(12) Patent Application Publication
(10) Pub. No.: US 2007/0045111 A1
(43) Pub. Date: Mar. 1, 2007

(54) Plasma excitation system

(76) Inventors: Alfred Trusch, Brelsach (DE); Markus Bannwarth, Frelburg (DE); Lothar Wolf, Sasbach (DE); Martin Steuber, Buggingen (DE); Sven Axenbeck, Neuenburg (DE); Peter Wiedemuth, Herbolzheim (DE)

Correspondence Address: J. Peter Fasse;FISH & RICHARDSON P.C., 225 Franklin Street, Boston, MA, 02110-2804, US

(21) Appl. No.: 11/318,344

(22) Filed: Dec. 23, 2005

Related U.S. Application Data
(60) Provisional application No. 60/675,856, filed on Apr. 29, 2005.

(30) Foreign Application Priority Data
Dec. 24, 2004 (EP) 04 030 764.7

(51) Int. Cl. C23C 14/00

(52) U.S. Cl. 204/298.38

(57) ABSTRACT

A plasma excitation system includes at least one DC current supply connected to a mains supply, at least one medium frequency (MF) unit connected to the at least one DC current supply for generating an AC voltage at its output, and a controller. The output of the MF unit is connected to electrodes of a coating chamber. The controller is connected to the at least one DC current supply for regulating and/or controlling an output value of the DC current supply, and is also connected to the at least one MF unit for regulating and/or controlling an output value of the MF unit. The controller includes at least one input interface for supplying a value describing an output value of the at least one MF unit, and at least one control output interface for connecting a control input of the at least one MF unit.

### CROSS REFERENCE TO RELATED APPLICATION

This application claims priority under 35 U.S.C. § 119(a) to and is a continuation of European Patent Application No. 04 030 764.7, filed Dec. 24, 2004, and this application claims priority to U.S. Application Ser. No. 60/675,856, filed Apr. 29, 2005, both of these applications are hereby incorporated by reference.

### TECHNICAL FIELD

The application relates to a plasma excitation system for supplying power to a plasma process.

### BACKGROUND

In flat panel display (FPD) manufacturing processes, large surfaces of a substrate, for example, glass panels, are uniformly coated in several steps. Coating of large glass surfaces through sputtering/cathode sputtering in plasma processes, in a reactive and also a conventional manner, is known from architecture glass coating. In such plasma processes, a current or voltage source generates a plasma that removes material from a target, and the removed material is deposited on the substrate, for example, the glass panel. Before depositing, the atoms of the target may bind to gas atoms or molecules in a reactive process, depending on the desired coating.

In architecture glass coating, the glass panel is continuously guided past a sputtering source in the plasma chamber (that is, the coating chamber). In this way, the coating can be applied more uniformly. The plasma is distributed homogeneously in only one axis, that is, in one dimension, and perpendicular to the direction of motion of the glass panel.

Architecture glass coating utilizes DC and also medium frequency (MF) sputtering processes. The latter are operated with medium frequency current supplies, wherein a controlled or uncontrolled intermediate circuit voltage is generated from a single-phase or multi-phase voltage. The intermediate circuit voltage is converted into a medium frequency (MF) AC voltage by an inverter circuit (for example, a bridge circuit). The MF output power signal is switched to an oscillating circuit, which is excited to oscillate. The oscillating circuit may be a series oscillating circuit or a parallel oscillating circuit. A series oscillating circuit is excited by an output power signal having a voltage source characteristic, whereas the parallel circuit is excited by an output power signal having a current source characteristic.

The MF power can be decoupled at the coil of the oscillating circuit and connected to two electrodes in a coating chamber of a coating system to enable plasma production in the coating chamber. The electrodes in an MF excitation system operate alternately as anode and cathode.

In some FPD manufacturing processes, the relatively larger-sized substrates may be planar coated from a stationary position, that is, without being continuously guided past the sputtering source. The surface area of a relatively larger-sized substrate can be a few square meters up to about tens of square meters, and the substrate should be coated during one work step. Moreover, the failure rate should be very low, and since an FPD is assembled from a single part, the systems, the plasma chambers, the electrodes, the targets, and the current supplies used during the manufacturing process should meet new requirements.

In a FPD manufacture process, DC current supplies have been used for exciting the plasma because DC current supplies can distribute the plasma in a relatively homogeneous manner in two dimensions, that is, over the entire surface of the substrate. Because of this, DC current supplies are particularly useful for coating substrates that are difficult to handle due to their size, and can therefore not be moved easily during coating.

Generally, more power is needed to coat the entire surface of the substrate in one work step. Moreover, to generate plasma for use in FPD manufacturing processes, current supplies run at a power of between 50 and 200 kW and more. Thus, current supplies could be reconfigured for operation between the individual power classes, such as, for example, from a 50 kW to 100 kW power class. DC current supplies are typically easier to reconfigure than MF current supplies. In plasma processes that use DC current supplies, several DC plasma excitation systems can be connected in parallel and to ensure that all plasma excitation systems supply the same power, a common regulation can be provided.

Current supplies operate with a finite efficiency, and therefore can generate a considerable amount of dissipated heat. Therefore, current supplies can be cooled using a coolant. For example, in FPD manufacturing, a coolant can be applied in the direct vicinity of the coating chambers. As further examples, DC current supplies can be air-cooled, while MF current supplies are typically cooled with a coolant because the MF current supplies can exhibit relatively larger heat losses than DC current supplies.

To reduce space, the coating processes that are sequentially performed during the manufacturing process are carried out in the same coating chamber. Towards this end, material can be removed from different targets within the coating chamber for each coating process, and the current supply can switch from one target to another so that one single current supply can be used for the different coating processes and different targets.

Often, in coating systems that are constrained to small spaces and the current supplies are positioned at remote locations, for example, in the cellar, and the current is supplied through relatively long cables to the coating chamber. Because DC cables are relatively inexpensive and flexible, DC current supplies can be positioned at remote locations and are therefore used in coating systems constrained to small spaces.

DC current supplies can sometimes produce arcs, in particular, in reactive processes, if the targets are not removed uniformly and insulating layers form on the targets.

### SUMMARY

In one general aspect, a plasma excitation system for coating large-surface substrates is described. The plasma excitation system includes at least one DC current supply that can be connected to a mains supply, at least one medium frequency (MF) unit connected thereto for generating an AC voltage at its output, and a controller that is connected to the at least one DC current supply for regulating and/or controlling an output value of the DC current supply. The output of the MF unit can be connected to electrodes of a coating chamber. The controller is also connected to the at least one MF unit for regulating and/or controlling an output value of the MF unit.

In the plasma excitation system of the above-mentioned type, the controller may include at least one input interface and at least one control output interface. The at least one input interface supplies a value describing an output value of the at least one MF unit. The at least one control output interface serves for connecting a control input of the at least one MF unit. The output value of the MF unit can be directly supplied to the controller. The value describing the output value is thereby the output value itself. It is also feasible to detect the output value by a measuring device that transfers the output value or a value describing the output value to the controller using the input interface. Several input and control output interfaces may be provided at the controller, and the controller can be connected to several MF units.

The current, voltage and/or power of the MF output signal can be measured and controlled, permitting access of the controller to the MF unit. By providing at least one input interface and at least one control output interface, the DC current supply can be simultaneously connected to several MF units. Depending on the regulation or control, power is supplied only to individual MF units, and may be supplied only to the desired MF units. DC power switches are therefore not required for switching off or deactivating one single MF unit. Since the MF units usually contain switching bridges, it is sufficient to control the MF units or the inverters containing switching bridges in such a manner that all switches are open. In this case, the inverter transfers no power, permitting operation of different processes, in particular, processes having different targets, with one common DC current supply. However, each electrode pair has its own MF unit that is matched to each electrode pair.

The DC current supplies and the MF units can be accommodated in different housings by providing the above-mentioned interfaces. This eliminates disturbing interferences.

In one implementation, the controller includes at least one further input interface and at least one further control output interface. The at least one further input interface serves for supplying an output value or a value describing an output value of the at least one DC current supply. The at least one control output interface serves for connecting a control input of the at least one DC current supply. The plasma excitation system therefore includes at least one DC current supply and one MF unit, wherein an intermediate circuit voltage is generated at the (power) output of the DC current supply, which is supplied to the MF unit. The controller can measure and regulate the current, voltage and/or power at the output of the DC current supply either directly or indirectly by way of corresponding measuring device. For this reason, not only the output value of the MF unit is used for regulation and control of the plasma coating process, but also the output value of the DC current supply is used for regulation and control of the plasma coating process.

Several DC current supplies can be connected to the controller in a simple manner by providing the described interfaces. Advantageously, the current, voltage and power can optionally be regulated at the output of the MF unit. This permits optimum adjustment of the excitation system to the respective plasma process.

In another implementation, the controller includes interfaces for connecting data and/or signal lines that are connected to the at least one DC current supply and/or the at least one MF unit. Signals, for example, of an arc detecting means, can thereby be transmitted in a fast and simple manner to the controller, which can then react thereto. The data lines serve for data and signal exchange between the MF unit and the controller or a master DC current supply. Data transmission may be performed analogously for measuring and regulation signals such as power measurement data, which is transmitted at a very high speed. The data is preferably exchanged by way of current interfaces instead of voltage interfaces, thereby improving the sensitivity to disturbances. Control, measuring and regulation signals that are transmitted at a relatively high speed and with high data security, such as, for example, signals describing arc detection, error states, etc. can be transmitted in a digital manner. Digital data transmission may be performed by way of a serial communication bus (for example, CAN) for signals that require very high data reliability but are less critical with time, for example, temperature monitoring signals.

In one implementation, the at least one DC current supply is located remotely from the at least one MF unit, in particular, at a distance of 1-50 m, and is connected to the at least one MF unit by way of a DC cable and measuring and control lines. The DC current supply does not have to be in the direct vicinity of the plasma system or coating chamber. The DC current supply therefore takes up no space in a hall in which the FPD is fabricated. The MF unit is lighter than a unit that would include both the DC current supply and the MF unit, and therefore the MF unit can be set up in a hall with underlying cellar. In this case, the DC current supply may advantageously be disposed below the MF unit. The DC cables and the control and measuring cables can be guided over long distances to the MF units that are positioned in the direct vicinity of the coating chamber and are connected by way of corresponding interfaces. This is advantageous in that expensive MF cables, which have a limited length and are less flexible than DC cables, can be omitted.

In another implementation, the at least one DC current supply is air-cooled. In this implementation, the at least one MF unit may be cooled by a coolant or by air. If only the MF unit is cooled by a coolant, less heat is dissipated to the coolant. It is more likely that the coolant is provided in the direct vicinity of the coating chamber that is close to the MF unit, than at a remote location, for example, in the cellar. Due to air cooling, the DC current supply does not depend on connection to a coolant, and can therefore be positioned at almost any location.

In another implementation, the at least one MF unit includes at least one first inverter for feeding an output oscillating circuit. The output oscillating circuit may be designed as series or parallel oscillating circuit. In order to obtain a current source characteristic, chokes may be provided at the input of the inverter. The inverter thereby generates an alternating voltage from an intermediate circuit voltage. The inverter can be designed as full bridge, in particular, as full bridge with controlled Insulated Gate Bipolar Transistors (that is, IGBTs). The MF unit may also include a control system for one or more inverters. The coil of the output oscillating circuit may represent the stray inductance on the primary side of an output transformer. The output transformer may be designed to galvanically separate the output oscillating circuit and the electrodes in the plasma chamber. In this case, neither the DC current supply nor the inverter needs to be provided with a galvanic separation. The output transformer may be formed with a coil around an air core to prevent saturation. The output of the output transformer may have several taps for adjusting the voltage and current to the respective electrode configuration.

In another implementation, several DC current supplies that are connected in parallel and can be connected to a mains supply are provided for generating a first intermediate circuit voltage, and the several DC current supplies are connected to the first inverter of the MF unit. Different power classes can be set using several parallel DC current supplies by connecting or disconnecting individual current supplies.

In one implementation, a measuring device for measuring the current, voltage and/or power at the output of the respective DC current supply is allocated to each DC current supply. The measuring device is connected to the controller. Each current supply may thereby have its own measuring device. The measuring device may also be disposed on the controller, in particular, be integrated therein. Separate arrangement thereof in the form of independent components is also feasible. Each DC current supply may be integrated in a separate housing that is provided with plug contacts (interfaces) for input voltage connections, output connections, and measuring, control and regulation connections, thus permitting rapid configuration. A controller may be accommodated in the housing of each DC current supply and take over the task of subordinate control. Thus, the controller can be quickly configured and exchanged.

In one implementation, the at least one MF unit includes at least one second inverter that is connected to the at least one DC current supply, such that the outputs of the first and second inverters are interconnected. The first and second inverters can be close to each other and have a symmetrical design. Their outputs are connected with low induction, and can be controlled by identical control signals. In this manner, interferences and phase shifts can be safely prevented.

Inverters of identical construction can be used to reduce the production costs. Low power components can be used to reduce the component costs. The simple configurability can be maintained because the second inverter can be put out of operation if no DC current supplies are connected thereto.

In another implementation, several DC current supplies, which are connected in parallel and can be connected to a mains supply, may be provided for generating a second intermediate circuit voltage, and the several DC current supplies are connected to the second inverter of the MF unit. Several groups of several DC current supplies that are connected in parallel can be provided. In this case, each group is connected to an inverter, and the inverters are interconnected upstream of an output oscillating circuit. Because the intermediate circuit voltages generated by the different groups remain separate, the DC current supplies may be regulated in such a manner that the bridges of the inverters are symmetrically loaded.

Each DC current supply may include one receptacle for the controller. A receptacle or slot may, for example, be provided on the housing of the DC current supply. Thus, by providing each DC current supply with a controller, each DC current supply may be designed as a master current supply that thereby includes a subordinate controller for all current supplies and provides reliable operation. With one single controller for all DC current supplies it can be ensured that all DC current supplies deliver approximately the same power, which additionally ensures uniform load of the inverters.

The plasma excitation system may include an arc detecting means. Arcs that are generated much less frequently during MF sputtering compared to DC sputtering, can be eliminated quickly in connection with an arc suppression and/or elimination means, and therefore cause only little damage. In particular, small residual arc energies can be ensured (<20 mJ/kW). Furthermore, the plasma excitation system may include a timing element (timer) that keeps the DC current supply switched off for a certain time interval in case of an arc. This interval can be adjusted within a range of between 100 μs and 100 ms. Arcs can thereby be safely eliminated and the current supply may be adjusted for different processes. Moreover, the arc detecting means may offer to set a time delay. Upon detection of an arc, the current is switched off after this time delay. Arcs that appear again and again even after switching off and switching on again, can thereby be burned down in a defined manner.

In another general aspect, the plasma excitation system described herein may be used in a large-surface plasma coating system for coating or producing flat panel displays. The large-surface plasma coating system includes the plasma excitation system, and a coating chamber with at least two electrodes that are connected to the plasma excitation system. Each electrode is connected to at least one target and the coating chamber includes one or more substrate holders or receptacles that are suited for supporting substrates having a surface ≧1 square meter. An output signal (voltage, current, or power) with a frequency within a range between about 20 and about 500 kHz, and in particular about 20 and about 100 kHz, can be generated at the output of the plasma excitation system, and a substantially homogeneous two-dimensional plasma can be generated in the coating chamber. The frequency range between about 20 and about 500 kHz and, in particular, the range between about 20 and about 100 kHz can be generated also for high powers (about 50 to about 200 kW) with simple and inexpensive switching technology. Because the frequency range is beyond the audible range, noisy oscillations are therefore reduced. This frequency range has also proven to be particularly advantageous for homogeneous plasma distribution.

This procedure improves and facilitates the generation of a homogeneous plasma using an MF current supply, that is, a plasma generation system including an MF unit, when compared to DC current supplies. The targets connected to the electrodes are removed much more uniformly so that homogeneous plasma distribution and hence homogeneous coating is ensured even for a long operating time.

Arcing is much less frequent in MF processes than in DC processes. To further minimize the coating problems involved with infrequent arcing, it may be possible to detect arcs and actively extinguish them upon detection or at least switch off the current supply or supplies or interrupt the energy supply from the current supplies to the coating chamber to thereby extinguish the arcs. After an extinguishing action, the plasma may be ignited again or the power supply into the coating chamber may be started again after a predetermined time.

In another general aspect, a method of coating a substrate includes controlling a first intermediate circuit voltage generated at each of a plurality of parallel-connected DC current supplies that each supply a DC current from a mains supply, and controlling an output value of a MF unit that generates an AC voltage from the DC current. Controlling the first intermediate circuit voltage includes receiving the first intermediate circuit voltage of the respective DC current supply through a measuring device coupled to an output of the respective DC current supply. Controlling the output value of the MF unit includes receiving the output value of the MF unit through a measuring device coupled to the output of the MF unit, and sending a signal to a control input of the MF unit.

In a further general aspect, a method of coating a substrate includes supporting one or more substrates, with each substrate having a surface area greater than 1 square meter, generating an AC voltage with a frequency in the range between about 20 and about 500 kHz an output connection of a plasma excitation system, and generating a substantially homogeneous two-dimensional plasma from at least two electrodes and their respective targets positioned within a coating chamber that is connected to the plasma excitation system.

Further advantages can be extracted from the description and the drawings. The features mentioned above and below may be used individually or collectively in arbitrary combination. The implementations shown and described are not to be understood as exhaustive enumeration but have exemplary character. Other features will be apparent from the description, the drawings, and the claims.

### DESCRIPTION OF DRAWINGS

FIG. 1 shows a schematic view of a large-surface plasma coating system;

FIG. 2 shows a first implementation of a plasma excitation system; and

FIG. 3 shows a second implementation of a plasma excitation system.

Like reference symbols in the various drawings may indicate like elements.

### DETAILED DESCRIPTION

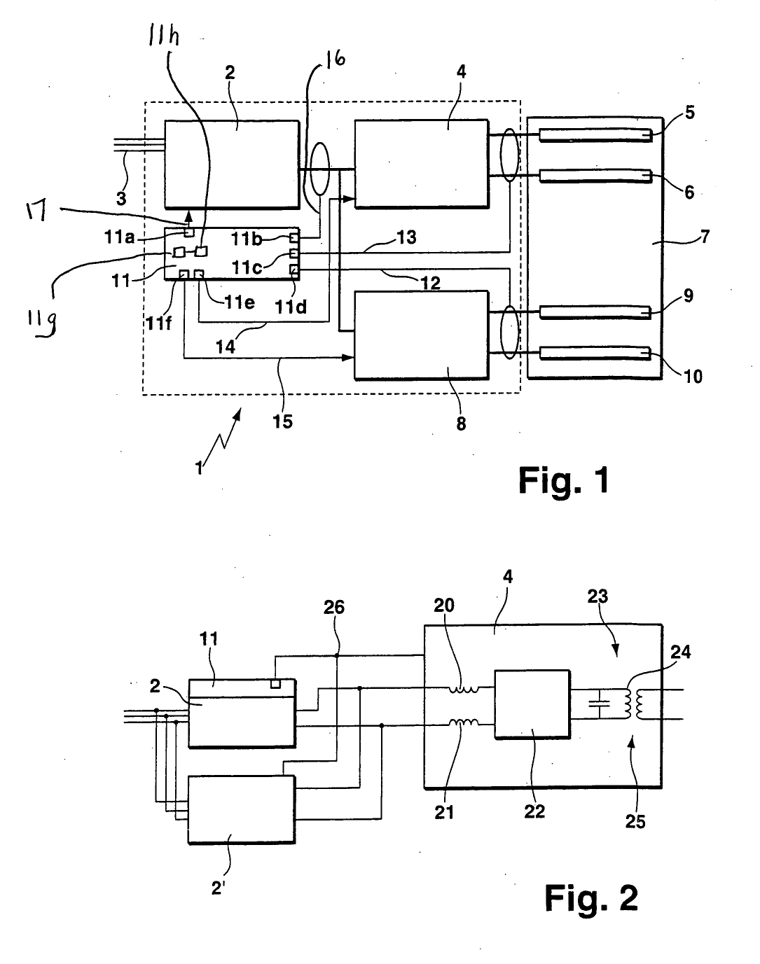

FIG. 1 shows a plasma excitation system 1 that is part of a large-surface plasma coating system, that is, a plasma coating system that coats substrates having relatively large surfaces. The plasma excitation system 1 includes a DC current supply 2 that is connected to a mains supply 3, and a first MF unit 4 that is connected to the DC current supply 2. The MF unit 4 is connected to electrodes 5, 6 that are disposed in a coating chamber 7. The plasma excitation system 1 also includes a second MF unit 8 that is arranged in parallel to the MF unit 4, and that is also connected to the DC current supply 2. The MF unit 8 is connected to electrodes 9, 10 that are disposed in the coating chamber 7. The coating chamber 7 can be used to coat large-surface substrates in part because the coating chamber 7 includes the plurality of electrodes 5, 6, 9, 10.

Each of the electrodes 5, 6, 9, 10 can be connected to one or more targets (not shown), which are placed adjacent their respective electrodes. Moreover, the targets on the electrodes 5, 6 and the targets on the electrodes 9, 10 may be made with different materials. The electrodes 5, 6, 9, 10 can be uniformly distributed relative to each other to improve uniform coating over the entire surface of the substrate.

The plasma excitation system 1 also includes a controller 11. The controller 11 receives an output value of the DC current supply 2 through a measuring device and line 16 at an interface 11b. The controller 11 regulates or controls the DC current supply 2 on the basis of the output value of the DC current supply 2 through a control line 17 connected to an interface 11a. Additionally, the controller 11 receives output values of the MF units 4, 8 through measuring devices or lines 12, 13 at respective interfaces 11d, 11c. The output values are detected and supplied to the controller 11 using any suitable technique. Based on the output values from the MF units 4, 8, the controller 11 regulates or controls the MF units 4, 8 through control lines 14, 15 connected to respective interfaces 11e, 11f. The measuring lines 12, 13 and the control lines 14, 15 may also be referred to as data lines. The interfaces 11a to 11f are provided on the controller 11 for connecting the DC current supply and the MF units 4, 8 or the lines 12 to 16 used for connection.

The plasma excitation system 1 may also include an arc detecting means 11h and a timer 11g. The arc detecting means 11h and the timer 11g can be placed in the controller 11, as shown in FIG. 1. In another implementation, one or both of the arc detecting means 11h and the timer 11g can be placed outside of the controller.

FIG. 2 shows an implementation of the plasma excitation system 1 of FIG. 1. In this implementation, the plasma excitation system 1 includes two DC current supplies 2, 2′, and the MF unit 4 includes an inverter 22 and an oscillating circuit 23. The DC current supplies 2 and 2′ generate an intermediate circuit voltage that is supplied to the inverter 22 of the MF unit 4 by way of chokes 20, 21. The DC current supply 2 is a master DC current supply and includes the controller 11. The controller 11 is connected to the MF unit 4 and the DC current supply 2′ by way of measuring, data, signal, and control lines 26. The inverter 22 feeds the oscillating circuit 23, which is designed as parallel oscillating circuit including an output transformer 25. The output transformer 25 includes as its primary inductance a coil 24. An MF voltage is output from the output transformer 25.

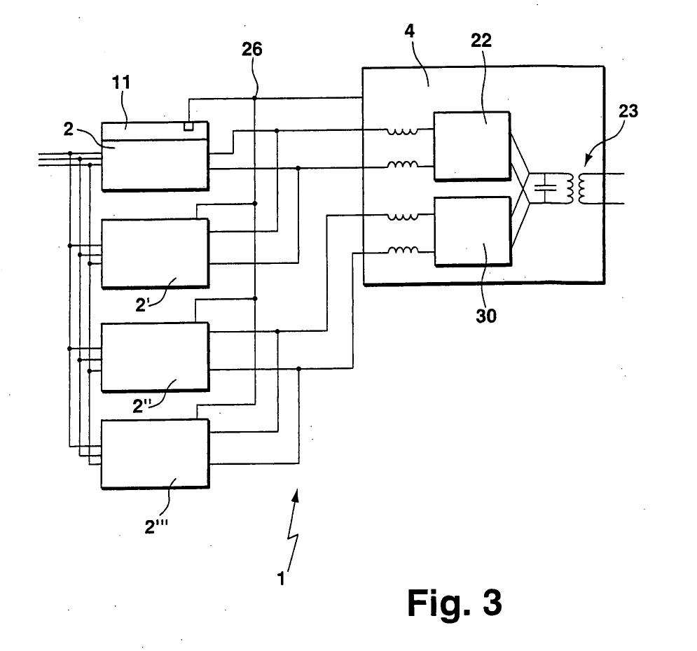

FIG. 3 shows another implementation of the plasma excitation system 1 of FIG. 1. In this implementation, the plasma excitation system includes two sets of DC current supplies 2, 2′ and 2″, 2′″, and the MF unit 4 includes a pair of inverters 22, 30 and an output oscillating circuit 23. Each DC current supply 2, 2′ and 2″, 2′″ within a set generates an intermediate circuit voltage that is applied to the respective inverter 22 or 30, as shown. The DC current supply 2 is a master current supply that includes the controller 11. The controller 11 regulates and/or controls the DC current supplies 2, 2′, 2″, 2′″ and the MF unit 4. The outputs of the inverters 22, 30 are connected with low induction, and they feed the output oscillating circuit 23. The DC current supplies 2, 2′, 2″, 2′″ are regulated to provide approximately the same power, which ensures a symmetrical load of the inverters 22 and 30. The MF unit 4 does not need to be configured to monitor the power from the DC current supplies 2, 2′, 2″, 2′″.

Other implementations are within the scope of the following claims. For example, the MF unit 4 can be configured to monitor the power from the DC current supply.

What is claimed is;

1. A plasma excitation system for supplying power to a plasma process, the plasma excitation system comprising:
at least one DC current supply that is configured to be connected to a mains supply,
at least one medium frequency (MF) unit connected to the at least one DC current supply for generating an AC voltage at its output, and
a controller that is connected to the at least one DC current supply for controlling an output value of the DC current supply, and that is also connected to the at least one MF unit for controlling an output value of the MF unit,
wherein the controller comprises:
at least one input interface that is connected to an output of the at least one MF unit to receive a value describing an output value of the at least one MF unit, and
at least one control output interface that is connected to a control input of the at least one MF unit, and
wherein a plurality of the DC current supplies are connected in parallel and are configured to generate a first intermediate circuit voltage.

2. The plasma excitation system of claim 1, wherein the at least one MF unit comprises at least one first inverter connected to an output oscillating circuit, wherein the DC current supplies are connected to the first inverter of the MF unit.

3. The plasma excitation system of claim 2, wherein the at least one MF unit comprises at least one second inverter that is connected to at least one DC current supply, wherein the outputs of the first and second inverters are interconnected.

4. The plasma excitation system of claim 3, wherein the at least one DC current supply that is connected to the MF unit is provided for generating a second intermediate circuit voltage, and is connected to the second inverter of the MF unit.

5. The plasma excitation system of claim 1, further comprising a measuring device connected to the output of the at least one DC current supply and to the controller, wherein the measuring device is configured to measure a current, a voltage, or a power at the output of the at least one DC current supply.

6. The plasma excitation system of claim 5, wherein the measuring device is connected to an input interface of the controller.

7. The plasma excitation system of claim 1, wherein each DC current supply comprises a receptacle for the controller.

8. A plasma coating system for coating flat panel displays, the plasma coating system comprising:
a plasma excitation system including at least one output connection, and
a coating chamber including:
at least two electrodes that are connected to the plasma excitation system and each connected to at least one target, and
one or more substrate holders that are each configured to support a substrate having a surface area greater than 1 square meter,
wherein the plasma excitation system is configured to generate an AC voltage with a frequency in the range between about 20 and about 500 kHz at the at least one output connection, and the coating chamber and the plasma excitation system are configured to generate a substantially homogeneous two-dimensional plasma in the coating chamber.

9. The plasma coating system of claim 8, wherein the plasma excitation system comprises:
at least one DC current supply that is configured to be connected to a mains supply,
at least one medium frequency (MF) unit connected to the at least one DC current supply for generating an AC voltage at its output, and
a controller that is connected to the at least one DC current supply for controlling an output value of the DC current supply, and that is also connected to the at least one MF unit for controlling an output value of the MF unit.

10. The plasma coating system of claim 9, wherein the controller comprises:
at least one input interface that is connected to an output of the at least one MF unit to receive a value describing an output value of the at least one MF unit, and
at least one control output interface that is connected to a control input of the at least one MF unit.

11. The plasma coating system of claim 10, wherein a plurality of the DC current supplies are connected in parallel and are configured to generate a first intermediate circuit voltage.

12. The plasma coating system of claim 9, wherein the at least one MF unit comprises at least one first inverter connected to an output oscillating circuit, wherein the DC current supplies are connected to the first inverter of the MF unit.

13. The plasma coating system of claim 12, wherein the at least one MF unit comprises at least one second inverter that is connected to at least one DC current supply, wherein the outputs of the first and second inverters are interconnected.

14. The plasma coating system of claim 13, wherein the at least one DC current supply that is connected to the MF unit is provided for generating a second intermediate circuit voltage, and is connected to the second inverter of the MF unit.

15. The plasma coating system of claim 9, further comprising a measuring device connected to the output of the at least one DC current supply and to the controller, wherein the measuring device is configured to measure a current, a voltage, or a power at the output of the at least one DC current supply.

16. The plasma coating system of claim 15, wherein the measuring device is connected to an input interface of the controller.

17. The plasma coating system of claim 9, wherein each DC current supply comprises a receptacle for the controller.

18. The plasma coating system of claim 8, wherein the plasma excitation system is configured to generate an AC voltage with a frequency in the range between about 20 and about 100 kHz

19. A method of coating a substrate, the method comprising:
controlling a first intermediate circuit voltage generated at each of a plurality of parallel-connected DC current supplies that each supply a DC current from a mains supply, wherein controlling the first intermediate circuit voltage includes receiving the first intermediate circuit voltage of the respective DC current supply through a measuring device coupled to an output of the respective DC current supply, and
controlling an output value of a MF unit that generates an AC voltage from the DC current, wherein controlling the output value of the MF unit includes:
receiving the output value of the MF unit through a measuring device coupled to the output of the MF unit, and
sending a signal to a control input of the MF unit.

20. A method of coating a substrate, the method comprising:
supporting one or more substrates, with each substrate having a surface area greater than 1 square meter,
generating an AC voltage with a frequency in the range between about 20 and about 500 kHz an output connection of a plasma excitation system, and
generating a substantially homogeneous two-dimensional plasma from at least two electrodes and their respective targets positioned within a coating chamber that is connected to the plasma excitation system.
